(19) United States
(12) Patent Application Publication
(10) Pub. No.: US 2020/0294727 A1
(43) Pub. Date: Sep. 17, 2020

(54) ORGANIC-INORGANIC HYBRID MATERIAL AND PEROVSKITE SOLAR CELL USING SAME

(71) Applicant: THE UNIVERSITY OF TOKYO, Tokyo (JP)

(72) Inventors: Hiroshi SEGAWA, Tokyo (JP); Takeru BESSHO, Tokyo (JP); Zeguo TANG, Tokyo (JP)

(73) Assignee: THE UNIVERSITY OF TOKYO, Tokyo (JP)

(21) Appl. No.: 16/611,332

(22) PCT Filed: May 10, 2018
(86) PCT No.: PCT/JP2018/018060

§ 371 Date: Jan. 27, 2020

(30) Foreign Application Priority Data
May 10, 2017 (JP) 2017-093656
Nov. 20, 2017 (JP) 2017-222393

(51) Int. Cl. H01G 9/20; H01L 51/00

(52) U.S. Cl. CPC H01G 9/2059; H01G 9/204; H01L 51/0077; H01G 9/2027; H01G 9/2031

(57) ABSTRACT

To provide a perovskite solar cell having a high conversion efficiency. An organic-inorganic hybrid material applicable to a perovskite solar cell having a first electrode, an electron transport compound layer arranged on the first electrode, a perovskite compound layer arranged on the electron transport compound layer, a hole transport layer arranged on the perovskite compound layer, and a second electrode arranged on the hole transport layer, the organic-inorganic hybrid material comprising a compound represented by “KₓA1_{y}A2_{z}PbX1ₚX2_{q}”. Wherein, K represents potassium, Pb represents lead, A1 and A2 represent freely selectable cations, which may be organic or inorganic, and may be same; X1 and X2 represent halogen atoms, which may be same; x represents a numerical value ranging from 0.01 to 0.20; and y, z, p and q represent freely selectable numerical values which satisfy x+y+z=1 and p+q=3.

### TECHNICAL FIELD

This invention relates to a novel organic-inorganic hybrid solar cell material, and a perovskite solar cell using the same.

### BACKGROUND ART

Utilization of renewable energies aimed at construction of low-carbon society has been expanding. Among them, solar cells have scored the highest rate of market expansion. The known solar cells, however, cost high for the production, so that innovative cost reduction for the solar cells have been awaited.

Various types of low-cost solar cells have been investigated and developed (for example, see Patent Literature 1, and Non-Patent Literatures 1, 2). These solar cells have a structure that contains a transparent electroconductive glass substrate, a porous metal oxide semiconductor arranged thereon, with a dye adhered on the surface, an electrolyte with a redox pair, and a counter electrode. Such solar cell needs no expensive equipment for the manufacturing, since the elements thereof is manufacturable while applying a printing system rather than relying upon vacuum processes, and is therefore expected to reduce the manufacturing cost. The solar cell however contains a volatile solvent, raising an issue of durability.

As a solution to the drawback, having been investigated are solid-state, dye-sensitized solar cells described below:

1) those using inorganic semiconductors (see Non-Patent Literatures 3 and 4, for example);

2) those using low-molecular organic hole transport materials (see Patent Literature 2, and Non-Patent Literatures 5 and 6, for example); and

3) those using electroconductive polymers (see Patent Literature 3, and Non-Patent Literature 7, for example).

The solar cell described in Non-Patent Literature 3 employs copper iodide as a material for composing a p-type semiconductor layer. The photoelectric conversion efficiency, reasonably good immediately after being manufactured, is known to halved within several hours typically due to increase of crystal grain size of copper iodide.

The solid-state, dye-sensitized solar cell using an organic hole transport layer, described in Non-Patent Literature 5, has been further improved (Non-Patent Literature 6). The solid-state, dye-sensitized solar cell using a triphenylamine compound, described in Patent Literature 2, has an electron transport layer formed by vacuum evaporation of the triphenylamine compound. Hence, the triphenylamine compound cannot reach internal voids in the porous semiconductor, only to demonstrate low conversion efficiency. For the solar cell described in Non-Patent Literature 6, a complex of nanotitania particle and the hole transport material is obtained by dissolving a spiro-type hole transport material into an organic solvent, followed by spin coating. Optimum thickness of a film of the nanotitania particle in this solar cell is, however, reported to be 2 μm or around, which is much thinner than 10 to 20 μm employed in solar cells using an iodine electrolyte. Hence, the amount of dye adhered on titanium oxide is few, only to achieve an insufficient level of photoelectron conversion efficiency.

Another report has been made on a solid-state solar cell that uses polypyrrole as an electroconductive polymer (see Non-Patent Literature 7). This solar cell again suffers from low conversion efficiency. The solid-state, dye-sensitized solar cell using a polythiophene derivative, as described in Patent Literature 3, has a charge transfer layer formed by electrolytic polymerization on a porous titanium oxide electrode with a dye adsorbed thereon, where the dye may unfortunately desorb from titanium oxide or may decompose.

In recent years, a report has been made on a solar cell allowing a perovskite-type compound to absorb light and to generate electricity (see Non-Patent Literature 8). The perovskite-type compound used in this solar cell shows strong absorption in the visible light region. The solar cell reported here was, however, revealed to have very poor stability.

Perovskite solar cells have also been known to intrinsically show large hystereses in the current-voltage curves, despite their excellent power conversion efficiency.

### CITATION LIST

### Patent Literature

[Patent Literature 1] JP-B2-2664194
[Patent Literature 2] JP-A-H11-144773
[Patent Literature 3] JP-A-2000-106223
[Patent Literature 4] WO07/100095

### Non-Patent Literature

[Non-Patent Literature 1] Nature, 353(1991)737
[Non-Patent Literature 2] J. Am. Chem. Soc., 115(1993)6382
[Non-Patent Literature 3] Semicond. Sci. Technol., 10(1995)1689
[Non-Patent Literature 4] Electrochemistry, 70(2002)432
[Non-Patent Literature 5] Synthetic Metals, 89(1997)215
[Non-Patent Literature 6] Nature, 398(1998)583
[Non-Patent Literature 7] Chem. Lett., (1997)471
[Non-Patent Literature 8] J. Am. Chem. Soc., 131(2009)6050
[Non-Patent Literature 9] Science, 338(2012)643

### SUMMARY OF THE INVENTION

### Technical Problem

It is therefore an object of this invention to solve the aforementioned problems, and to provide a novel organic-inorganic hybrid material having a small distribution of conversion efficiency and a small hysteresis that appears in the current-voltage curve, and a solar cell using the same.

### Solution to Problem

Engaged in efforts to solve the aforementioned problems, the present inventors found that an organic-inorganic hybrid material with a small amount of potassium (K) added thereto as an inorganic monovalent cation can provide a high-performance perovskite solar cell, and arrived at this invention. The aforementioned problems were solved by the means below:

<0> An organic-inorganic hybrid material applicable to a perovskite solar cell having, on a first electrode, a first electrode having an electron transport compound layer arranged thereon, a perovskite compound layer arranged on the electron transport compound layer, a hole transport layer arranged on the perovskite compound layer, and a second electrode arranged on the hole transport layer,

the organic-inorganic hybrid material comprising a compound represented by formula 1 below, with potassium (K) added as a small amount of inorganic monovalent cation: Formula

KₓA1_{y}A2_{z}PbX1ₚX2_{q}

(where, K represents potassium, Pb represents lead, A1 and A2 represent freely selectable monovalent cations, which may be organic or inorganic, and may be the same; X1 and X2 represent halogen atoms, which may be the same; x represents a numerical value ranging from 0.01 to 0.20; and y, z, p and q represent freely selectable numerical values which satisfy x+y+z=1 and p+q=3).

<1> An organic-inorganic hybrid material applicable to a perovskite solar cell having a first electrode, an electron transport compound layer arranged on the first electrode, a perovskite compound layer arranged on the electron transport compound layer, a hole transport layer arranged on the perovskite compound layer, and a second electrode arranged on the hole transport layer,

the organic-inorganic hybrid material comprising a compound represented by formula 1 below, with potassium (K) added as a small amount of inorganic monovalent cation: Formula 1

KₓA1_{y}A2_{z}PbX1ₚX2_{q}

(where, K represents potassium, Pb represents lead, A1 and A2 represent freely selectable cations, which may be organic or inorganic, and may be the same; X1 and X2 represent halogen atoms, which may be the same; x represents a numerical value ranging from 0.01 to 0.20; and y, z, p and q represent freely selectable numerical values which satisfy x+y+z=1 and p+q=3).

<2> The organic-inorganic hybrid material according to <1>, wherein the compound represented by formula 1 is formed by a mixture of a lead halide and a non-lead divalent metal cation halide, together with a monovalent cation halide.

<3> The organic-inorganic hybrid material according to <1>, wherein the compound represented by formula 1 is formed by a lead halide and a monovalent cation halide.

<4> The organic-inorganic hybrid material according to <2> or <3>, wherein the monovalent cation halide contains a potassium halide.

<5> The organic-inorganic hybrid material according to <2> or <3>, wherein the monovalent cation halide contains a potassium halide and an alkylammonium halide.

<6> The organic-inorganic hybrid material according to <1>, wherein the compound represented by formula 1 is formed using an alkylammonium halide.

<7> The organic-inorganic hybrid material according to <5> or <6>, wherein the alkylammonium halide contains either a methylammonium halide or a formamidinium halide.

<8> The organic-inorganic hybrid material according to any one of <1> to <7>, wherein the electron transfer compound is at least one of zinc oxide, tin oxide, titanium oxide, aluminum oxide, niobium oxide and yttrium oxide.

<9> A perovskite solar cell comprising the organic-inorganic hybrid material described in any one of <1> to <8>.

### Advantageous Effects of Invention

The solar cell that employs the organic-inorganic hybrid material of this invention can provide excellent characteristics including distribution of conversion efficiency and hysteresis in the current-voltage curve, which are smaller than those in the prior art.

### BRIEF DESCRIPTION OF DRAWINGS

FIG. 1 is a structural drawing illustrating a perovskite solar cell of this embodiment.

FIG. 2 is a structural drawing illustrating a perovskite solar cell of this embodiment.

FIG. 3 is a structural drawing illustrating a perovskite solar cell of this embodiment.

FIG. 4 is a graph illustrating I-V curves of a perovskite solar cell of Example 1.

FIG. 5 is a graph illustrating I-V curves of the perovskite solar cell of Example 1.

FIG. 6 is a graph illustrating hysteresis factors of perovskite solar cells of Example 1 and Comparative Example 1.

FIG. 7 is a histogram illustrating distribution of conversion efficiency of the perovskite solar cell of Example

FIG. 8 is a SEM image of a perovskite compound layer in Example 1.

FIG. 9 shows band gap energy diagrams of the perovskite compound layers of the perovskite solar cells of Example 1 and Comparative Example 1.

FIG. 10 is a graph illustrating transient response characteristics of the perovskite solar cells of Example 1 and Comparative Example 1.

FIG. 11 is a graph illustrating I-V curves of the perovskite solar cell of Comparative Example 1.

FIG. 12 is a SEM image of the perovskite compound layer in Comparative Example 1.

FIG. 13 is an XRD chart (20) of the perovskite compounds.

### DESCRIPTION OF EMBODIMENTS

This invention, which firstly relates to an “organic-inorganic hybrid material” and a “perovskite solar cell” having such “organic-inorganic hybrid material” with the structures described in <1> above, additionally encompasses “perovskite solar cells” and “organic-inorganic hybrid materials” embodied as <2> to <8> below, as will be understood later from the detailed description.

<2> The organic-inorganic hybrid material of <1> and a perovskite solar cell, wherein the compound represented by formula 1 is formed by a mixture of a lead halide and a non-lead divalent metal cation halide, together with a monovalent cation halide.

<3> The organic-inorganic hybrid material of <1> and a perovskite solar cell, wherein the compound represented by formula 1 is formed by a lead halide and a monovalent cation halide.

<4> The organic-inorganic hybrid material of <2> or <3> and a perovskite solar cell, wherein the monovalent cation halide contains a potassium halide.

<5> The organic-inorganic hybrid material of <2> or <3> and a perovskite solar cell, wherein the monovalent cation halide contains a potassium halide and an alkylammonium halide.

<6> The organic-inorganic hybrid material of <1> and a perovskite solar cell, wherein the compound represented by formula 1 is formed using an alkylammonium halide.

<7> The organic-inorganic hybrid material of <5> or <6>, wherein the alkylammonium halide contains either a methylammonium halide or a formamidinium halide.

<8> The organic-inorganic hybrid material of any one of <1> to <7> and a perovskite solar cell, wherein the electron transfer compound is at least one of zinc oxide, tin oxide, titanium oxide, aluminum oxide, niobium oxide and yttrium oxide.

The organic-inorganic hybrid material of this invention is a compound represented by formula 1, and contains a very small amount of potassium. The organic-inorganic hybrid material of this invention is presumed to be a compound with the ABC₃-type crystal structure, that is, a compound with the perovskite-type structure. The compound is further presumed to have a distortion in the lattice structure, due to substitution of a part of constituent atoms of the perovskite-type structure with potassium atoms. Such distortion in the crystal lattice is presumed to suppress grain boundary from generating during crystal growth, and helps the compound demonstrate excellent electrical characteristics. It is therefore presumed that, as described later in EXAMPLE, employment of the organic-inorganic hybrid material to the perovskite solar cell can make the perovskite solar cell with high conversion efficiency and small hysteresis.

With the structures described in <2> to <7>, it now becomes possible to provide the perovskite solar cells with good conversion efficiency, in addition to the features described above in “ADVANTAGEOUS EFFECTS OF INVENTION”.

With the structure described in <8>, the electrons can more efficiently migrate since the metal oxide is used for the electron transport layer, and thereby it further becomes possible to provide the perovskite solar cell with further improved conversion efficiency.

This invention will be detailed below.

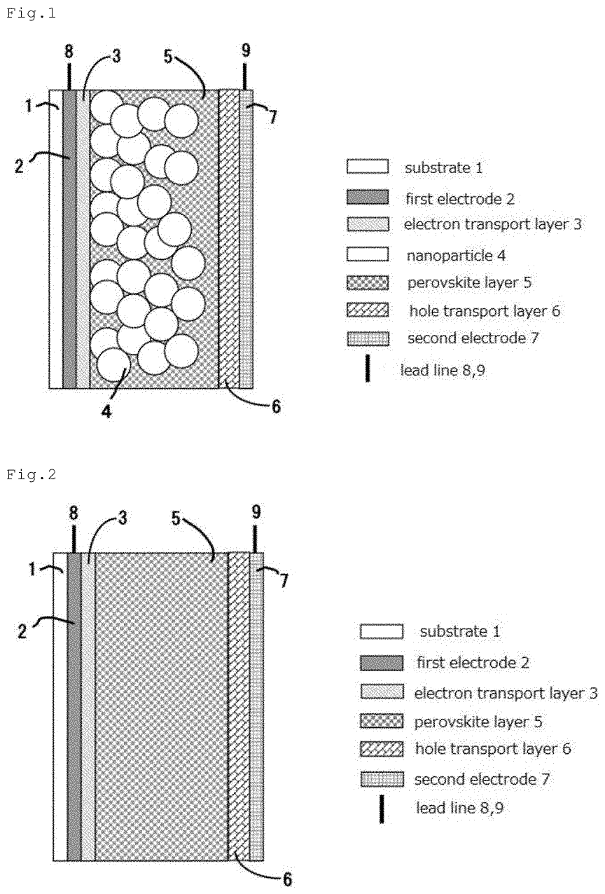

Structures of the perovskite solar cells will be explained referring to FIGS. 1 to 3.

In an embodiment illustrated in FIG. 1, a first electrode 2 is arranged on a substrate 1. On the first electrode 2, sequentially arranged are a dense electron transport layer 3, and a layer in which nanoparticles 4 are deposited. On the layer in which the nanoparticles 4 are deposited, arranged are perovskite layer 5, a hole transport layer 6, and a second electrode 7 in this order. The first electrode 2 and the second electrode 7 have lead lines 8 and 9 respectively attached thereto.

In an embodiment illustrated in FIG. 2, the first electrode 2 is arranged on the substrate 1. On the first electrode 2, arranged are the electron transport layer 3, the perovskite layer 5, the hole transport layer 6, and the second electrode 7 in this order. The first electrode 2 and the second electrode 7 have the lead lines 8 and 9 respectively attached thereto. Such structure is a so-called planar structure.

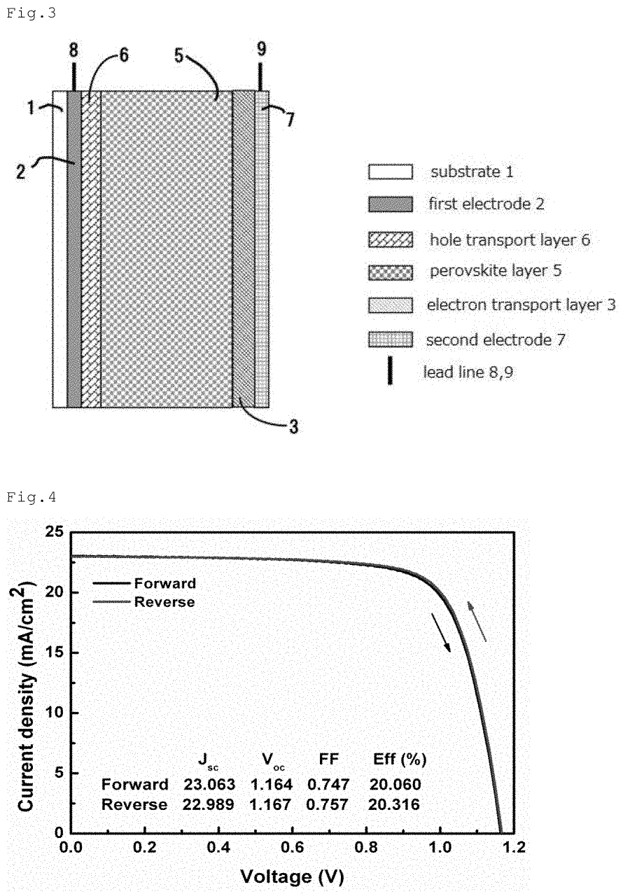

In an embodiment illustrated in FIG. 3, the first electrode 2 is arranged on the substrate 1, and arranged further thereon are the hole transport layer 6, the perovskite layer 5, the electron transport layer 6, and the second electrode 7 in this order. The first electrode 2 and the second electrode 7 have the lead lines 8 and 9 respectively attached thereto. Such structure is a so-called inverted structure.

The perovskite solar cell of this invention may have any of structures illustrated in FIGS. 1 to 3.

Note that, in the embodiments illustrated in FIGS. 1 and 2, the first electrode 2 corresponds to the “first electrode” specified in claim 1, and the second electrode 7 corresponds to the “second electrode” of the same. Meanwhile in the embodiment illustrated in FIG. 3, the second electrode 7 corresponds to the “first electrode” specified in claim 1, and the first electrode 2 corresponds to the “second electrode” of the same.

### <Substrate>

The substrate 1 used in this invention need to keep a certain level of hardness. Materials applicable to the substrate 1 are exemplified by glass, transparent plastic plate, transparent plastic film, and inorganic transparent crystal material.

### <First Electrode>

The first electrode 2 used in this invention is arranged on the substrate 1. The first electrode 2 is composed of an electroconductive substance transparent to visible light or a metal, for which any of known materials used for ordinary photoelectron conversion elements or liquid crystal panels are applicable. The materials are exemplified by indium tin oxide (referred to as ITO, hereinafter), fluorine-doped tin oxide (referred to as FTO, hereinafter), antimony-doped tin oxide (referred to as ATO, hereinafter), indium zinc oxide, niobium titanium oxide, graphene, and metals such as gold, silver, Pt, Ti and Cr. Among them, a single material may be used to form a monolayer, or a plurality of materials may be stacked. The first electrode 2 is preferably 5 nm to 100 μm thick, and more preferably 50 nm to 10 μm thick.

The first electrode 2 may be provided with a metal lead or the like. Materials for composing the metal lead are exemplified by metals such as aluminum, copper, silver, gold, platinum, and nickel. The metal lead may be formed on the substrate by vacuum evaporation, sputtering, crimping or the like, over which ITO or FTO may be applied.

### <Electron Transport Layer>

In the perovskite solar cells embodied as illustrated in FIGS. 1 and 2, a layer composed of an electron transfer compound which is a semiconductor (also referred to as “electron transport layer”, hereinafter) is arranged on the first electrode 2. The electron transport layer may have a dense electron transport layer formed on the first electrode 2, and a porous layer of nanoparticles 4 further formed thereon. Thickness of the dense electron transport layer is preferably, but not specifically limited to, 5 nm to 1 μm, and is more preferably 20 nm to 700 nm. Note, the term “dense” regarding the electron transport layer means that the semiconductor is filled with a packing density larger than that of the nanoparticles in the layer of nanoparticles 4.

The layer of nanoparticles 4 may be a single layer or a multilayer. The multilayer may be formed by repeatedly coating dispersions containing nanoparticles with different particles sizes, or by repeatedly coating dispersions containing different kinds of nanoparticles, or having different compositional ratios of resin and additives. Such multiple coating is an efficient technique for the case where the thickness is not sufficient after a single time of coating. The layer of nanoparticles is preferably 5 nm to 1 μm thick.

Any of known semiconductors (electron transfer compounds) may be used for the electron transport layer, without special limitation.

Specific examples include element semiconductors such as silicon and germanium; compound semiconductors represented by metal chalcogenides; organic electron acceptor materials such as fullerene; and compounds having perovskite structure.

Among them, oxide semiconductors are preferable; and titanium oxide, zinc oxide, tin oxide and niobium oxide are more preferable, each of which may be used independently, or two or more of which may be used in mixed manner. Crystal forms of these semiconductors is not specifically limited, and is selectable from single crystal, polycrystal and amorphous.

The nanoparticles may have size not specifically limited, wherein the primary particle preferably has an average particle size of 1 to 100 nm, which is more preferably 5 to 50 nm. It is also acceptable to improve the efficiency by mixing or stacking nanoparticles with a larger average particle size, in expectation of an effect of scattering incident light. In this case, the semiconductor preferably has an average particle size of 50 to 500 nm.

The nanoparticle may be an insulator, or any of the aforementioned semiconductors.

The electron transport layer 3 may be manufactured by any of methods not specifically limited, which are exemplified by methods based on film formation in vacuum such as sputtering, or wet film formation. The wet film formation is particularly preferable from the viewpoint of manufacturing cost. A preferred method is such as preparing a paste having semiconductor fine powder or sol dispersed therein, and then coating it over the first electrode. Methods of coating when applying the wet film formation may follow any of known methods without special limitation. Examples of applicable methods include, dipping, spray coating, wire bar coating, spin coating, roller coating, blade coating, and gravure coating, as well as wet printing processes such as relief printing, offset printing, gravure printing, intaglio printing, rubber plate printing, and screen printing.

Preferred methods of manufacturing the layer of nanoparticles 4 are such as coating a nanoparticle-containing composition, the nanoparticles are electrically contacted together, and then subjecting the coated film to firing, microwave irradiation, electron beam irradiation or laser irradiation, for enhanced film strength or enhanced adhesiveness with the substrate. Each of these processes may be carried out independently, or two or more of them may be carried out in a combined manner.

The firing, when employed, may be carried out within a temperature range not specifically limited. Too high temperature would, however, elevate the resistivity of the substrate and would melt the substrate, so that the temperature preferably ranges from 30 to 700° C., and more preferably from 100 to 600° C. Firing time is preferably, but not specifically limited to, 10 minutes to 10 hours. The firing may be followed by chemical plating using aqueous solution or aqueous-organic mixed solution of titanium tetrachloride, or by electrochemical plating using aqueous titanium trichloride solution. The microwave may be irradiated from the side on which the electron transport layer is formed, or from the back side. Irradiation time is preferably within one hour, but not specifically limited thereto.

### <Perovskite Compound Layer>

The perovskite compound layer 5 is composed of the organic-inorganic hybrid material of this invention. The organic-inorganic hybrid material is a compound represented by formula 1 below, which is a composite substance of organic compound and inorganic compound, and preferably has a perovskite-type structure. The organic-inorganic hybrid material of this invention, since being a compound that shows the perovskite-type structure, will be referred to as “perovskite compound” hereinafter. Formula 1

KₓA1_{y}A2_{z}PbX1ₚX2_{q}

(where, K represents potassium, Pb represents lead, A1 and A2 represent freely selectable cations, which may be organic or inorganic, and may be the same; X1 and X2 represent halogen atoms, which may be the same; x represents a numerical value ranging from 0.01 to 0.20; and y, z, p and q represent freely selectable numerical values which satisfy x+y+z=1 and p+q=3).

Each of y, z, p and q independently represents a freely selectable numerical value; and x+y+z=1 and p+q=3 mean that x+y+z and p+q will have values of 1 and 3, respectively, after rounded to the nearest whole number.

More specifically, each of X1 and X2 is independently exemplified by halogen atoms such as fluorine, chlorine, bromine and iodine atoms, which may be used independently, or in the form of mixture. A preferred embodiment is such as having both of p and q representing values exceeding 0, and, either one of X1 and X2 represents iodine, and the other represents bromine.

Each of A1 and A2 may independently represent organic monovalent cations such as methylammonium, ethylammonium, n-butylammonium and formamidinium.

In this invention, the compound represented by formula 1 above is preferably a compound formed by a mixture of lead halide and a non-lead divalent metal cation halide, together with a monovalent cation halide; and is more preferably a compound formed by lead halide together with monovalent cation halide. The monovalent cation halide preferably contains potassium halide, and more preferably contains potassium halide and alkylammonium halide. The alkylammonium halide is preferably at least one species selected from methylammonium halide and formamidinium halide. The lead halide is preferably lead iodide or lead bromide. The potassium halide is preferably potassium iodide or potassium bromide.

The organic-inorganic hybrid material of this invention (referred to as “perovskite compound”, hereinafter) may be formed by one-stage deposition process by which metal halide and alkylammonium halide, more preferably lead halide, potassium halide and alkylammonium halide, are dissolved or dispersed in a solvent to prepare a liquid, the liquid is then coated over the electron transport layer 3 or the hole transport layer 6 and then dried; or by two-stage deposition process by which metal halide dissolved or dispersed in a solvent is coated over the electron transport layer 3 or the hole transport layer 6 and dried, followed by immersion in a solution obtained by dissolving alkylammonium halide into a solvent, to thereby form the perovskite compound.

The drying, when the one-stage deposition process is employed, may be carried out while blowing poor solvent such as hexane or toluene, or gas such as nitrogen gas.

Possible methods for coating over the electron transport layer or the hole transport layer 6 include immersion, spin coating, spray coating, dipping, roller coating, and air knife coating. It is also acceptable to cause deposition on the electron transport layer or the hole transport layer 6 in a supercritical fluid using carbon dioxide or the like.

For the two-stage deposition process, possible methods for bringing the alkylammonium halide solution into contact with the electron transport layer 3 or the hole transport layer 6 having the metal halide preliminarily formed thereon, include immersion, spin coating, spray coating, dipping, roller coating, and air knife coating. It is also acceptable to cause deposition in a supercritical fluid using carbon dioxide or the like.

### <Hole Transport Layer>

The hole transport layer 6 may be formed using either liquid electrolyte or solid hole transport compound, and is preferably formed using solid hole transport compound.

The hole transport compound may be either inorganic compound or organic compound. The inorganic hole transport layer using the inorganic solid compound is formed within the electrode, by applying copper iodide, copper thiocyanate or the like, typically by casting, coating, spin coating, immersion, or electroplating.

The organic solid compound may be used to form a monolayer composed of a single material, or a stacked structure composed of a plurality of compounds. For the stacked structure, a polymer material is preferably used for the organic hole transport layer which is in contact with the second electrode 7. This is because use of the polymer material featured by its good film forming ability can make the surface of the amorphous electron transport layer 3 more smoother, and can improve the photoelectric conversion efficiency.

The organic hole transport material used independently for the monolayer structure may be any of known organic hole transport compounds, which are specifically exemplified by oxadiazole compound disclosed typically in JP-B-S34-5466, triphenylmethane compound typically disclosed in JP-B-S45-555, pyrazoline compound typically disclosed in JP-B-S52-4188, hydrazone compound typically disclosed in JP-B2-S55-42380, oxadiazole compound typically disclosed in JP-A-S56-123544, tetraarylbenzidine compound typically disclosed in JP-A-S54-58445, and stilbene compound typically disclosed in JP-A-S58-65440 or JP-A-S60-98437.

The polymer material, used for the organic hole transport layer in contact with the second electrode 7 in the stacked structure, may be any of known polymer materials with hole transport property.

Various additives may be added to the aforementioned inorganic and organic charge transport materials.

The additives are exemplified by iodine; metal iodides such as lithium iodide, sodium iodide, potassium iodide, cesium iodide, calcium iodide, copper iodide, iron iodide, and silver iodide; quaternary ammonium salts such as tetraalkylammonium iodide and pyridinium iodide; metal bromides such as lithium bromide, sodium bromide, potassium bromide, cesium bromide and calcium bromide; quaternary ammonium bromides such as tetraalkylammonium bromide and pyridinium bromide; metal chlorides such as copper chloride and silver chloride; metal acetates such as copper acetate, silver acetate, and palladium acetate; metal sulfates such as copper sulfate and zinc sulfate; metal complexes such as ferrocyanate salt-ferricyanate salt and ferrocene-ferricinium ion; sulfur compounds such as sodium polysulfide and alkyl thiol-alkyl disulfide; viologen dye; hydroquinone; ionic liquids described in Inorg. Chem., 35(1996)1168, such as 1,2-dimethyl-3-n-propylimidazolium iodide, 1-methyl-3-n-hexylimidazolium iodide, 1,2-dimethyl-3-ethylimidazolium trifluoromethanesulfonate, 1-methyl-3-butylimidazolium nonafluorobutylsulfonate, and 1-methyl-3-ethylimidazolium bis(trifluoromethyl)sulfonylimide; basic compounds such as pyridine, 4-t-butylpyridine and benzimidazole; and lithium compounds such as lithium trifluoromethanesulfonylimide and lithium diisopropylamide.

For the purpose of improving the electroconductivity, it is also acceptable to add an oxidant for converting a part of the organic charge transport substance to a radical cation.

The oxidant is exemplified by tris(4-bromophenyl)aminium hexachloroantimonate, silver hexafluoroantimonate, nitrosonium tetrafluoroborate, and silver nitrate. The organic hole transport material is not necessarily oxidized over the entire range, instead a partial oxidation will suffice. The added oxidant may be taken out of the system, or may be left unremoved.

The hole transport layer 6 is preferably formed directly on the perovskite layer 5. The hole transport layer 6 may be manufactured by any of methods not specifically limited, which are exemplified by methods based on film formation in vacuum such as vacuum evaporation, or wet film formation. The wet film formation is particularly preferable from the viewpoint of manufacturing cost.

Methods of coating when applying the wet film formation may follow any of known methods without special limitation. Examples of applicable methods include dipping, spray coating, wire bar coating, spin coating, roller coating, blade coating, and gravure coating, as well as printing processes such as relief printing, offset printing, gravure printing, intaglio printing, rubber plate printing, and screen printing. The film formation may take place in a supercritical fluid or in a subcritical fluid.

Before providing the second electrode 7, a metal oxide layer may be provided between the hole transport layer 6 and the second electrode 7. The metal oxide is exemplified by molybdenum oxide, tungsten oxide, vanadium oxide and nickel oxide. Molybdenum oxide is particularly preferable.

Methods of providing the metal oxide layer over the hole transport layer are not specifically limited, which are exemplified by methods based on film formation in vacuum such as sputtering and vacuum evaporation, or wet film formation.

A preferred method of the wet film formation is such as preparing a paste having metal oxide fine powder or sol dispersed therein, and then coating it over the hole transport layer.

Methods of coating when applying the wet film formation may follow any of known methods without special limitation. Examples of applicable methods include dipping, spray coating, wire bar coating, spin coating, roller coating, blade coating, and gravure coating, as well as printing processes such as relief printing, offset printing, gravure printing, intaglio printing, rubber plate printing, and screen printing.

Thickness of the metal oxide layer is preferably, but not specifically limited to, 0.1 to 50 nm, which is more preferably 1 to 10 nm.

### <Second Electrode>

The second electrode 7 may be formed over the substrate. The second electrode 7 may be made, for example, of metals such as platinum, gold, silver, copper, aluminum, rhodium and indium; carbonaceous compounds such as graphite, fullerene, and carbon nanotube; electroconductive metal oxides such as ITO, fluorine-doped tin oxide (referred to as FTO, hereinafter), and antimony-doped tin oxide (referred to as ATO, hereinafter); and electroconductive polymers such as polythiophene and polyaniline.

The thickness of the second electrode 7 is not specifically limited. The second electrode 7 may employ each of the aforementioned materials independently, or two or more materials in a mixed or stacked manner.

In this invention, the device may be formed while employing an inverted structure. The device with the inverted structure (as illustrated in FIG. 3) is obtainable by forming the aforementioned electron transport layer 3 and the hole transport layer 6 in inverted order.

### EXAMPLE

### Test Example 1

### Example 1

### (Manufacture of Titanium Oxide Semiconductor Electrode)

2 ml of titanium tetra-n-propoxide, 4 ml of acetic acid, 1 ml of deionized water 1 ml, and 40 ml of 2-propanol were mixed, the resultant solution was spin-coated over a FTO glass substrate, the coating was dried at room temperature, and then fired in the air at 450° C. for 30 minutes. The same solution was spin-coated again over the thus obtained electrode, to a thickness of 50 nm, the coating was fired in the air at 450° C. for 30 minutes, to thereby form the dense electron transport layer.

Over the dense electron transport layer, 18NR-T (titanium oxide paste) from Dyesol Ltd. was spin-coated to a thickness of 300 nm, the coating was dried at 120° C. for 3 minutes under hot air, and then fired in the air at 500° C. for 30 minutes, to thereby form the porous electron transport layer.

### (Manufacture of Perovskite Compound Layer)

Into an N,N-dimethylformamide solution (1.0 ml) having lead(II) iodide (0.507 mg), lead(II) bromide (0.073 mg), formamidinium iodide (0.172 mg), and methylammonium bromide (0.022 mg) dissolved therein, added was 100 μL of a dimethylsulfoxide solution with potassium(I) iodide (249 mg/mL), dissolved therein, to thereby prepare a perovskite precursor solution. The precursor solution was then applied dropwise and spin-coated over the substrate having the electron transport layer formed thereon, so as to form a perovskite film of 500 nm thick.

### (Manufacture of Hole Transport Layer)

A chlorobenzene solution having 2,2′,7,7′-tetrakis(N,N-di-p-methoxyphenylamine)-9,9′-spirofluorene (100 mM), and lithium bis(trifluoromethanesulfonyl)imide (27 mM), and 4-t-butylpyridine (110 mM) dissolved therein was spin-coated, and the coating was allowed to dry naturally. Gold was then allowed to deposit thereon in vacuum to a thickness of approximately 100 nm, to thereby manufacture the solar cell with a structure illustrated in FIG. 1.

### (Evaluation of Solar Cell Characteristics)

The thus obtained solar cell was measured regarding the photoelectric conversion efficiency under illumination of simulated sunlight (AM 1.5, 100 mW/cm²). The measurement employed simulated sunlight YSS-80 from Yamashita Denso Corporation, and an evaluation equipment ModuLab M-2A from TOYO Corporation. Good results were obtained, including an open circuit voltage of 1.16 V, a short circuit current density of 23.0 mA/cm², a shape factor of 0.76, and a conversion efficiency of 20.3%. I-V (current-voltage) characteristic of the solar cell was measured, and results are shown in FIG. 4. From FIG. 4, it was confirmed that the perovskite compound (Example 1) made from the mixture of lead(II) iodide and potassium(I) iodide showed, in the I-V measurement, almost no difference between current value detected when the potential was shifted from the state of short circuit current to the state of open circuit voltage, and current value detected when the potential was shifted from the state of open circuit voltage to the state of short circuit current, meaning that there was almost no hysteresis.

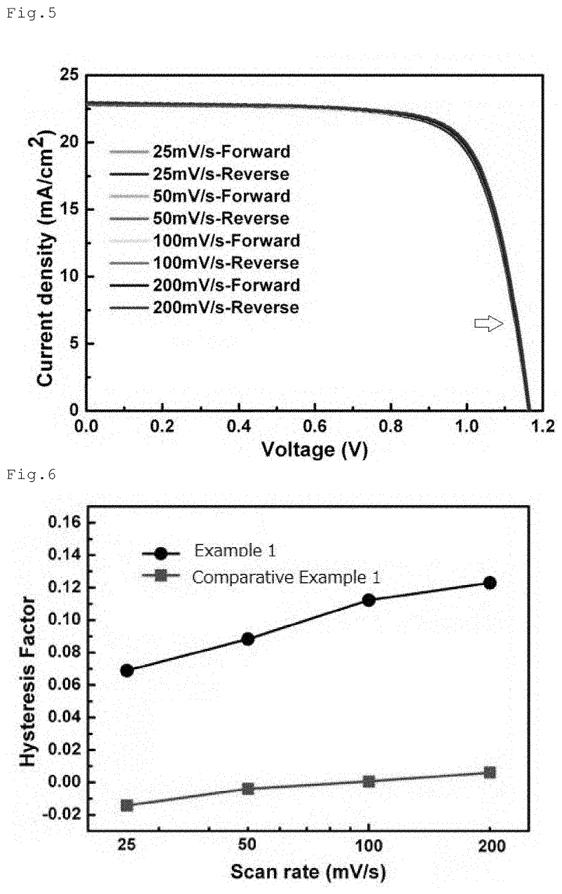

Meanwhile, FIG. 5 illustrates I-V curves measured under varied scan rates, and FIG. 6 illustrates hysteresis factors measured under varied scan rates. FIG. 5 shows, at the position indicated by an arrow from the left to right, forward I-V curve measured at a scan rate of 200 mV/s (200 mV/s-Forward), forward I-V curve measured at a scan rate of 100 mV/s (100 mV/s-Forward), forward I-V curve measured at a scan rate of 50 mV/s (50 mV/s-Forward), forward I-V curve measured at a scan rate of 25 mV/s (25 mV/s-Forward), reverse I-V curve measured at a scan rate of 200 mV/s (200 mV/s-Reverse), reverse I-V curve measured at a scan rate of 100 mV/s (100 mV/s-Reverse), reverse I-V curve measured at a scan rate of 50 mV/s (50 mV/s-Reverse), and reverse I-V curve measured at a scan rate of 25 mV/s (25 mV/s-Reverse). A hysteresis factor of Example 1 shown in FIG. 6 was calculated from the I-V curves shown in FIG. 5. From FIGS. 5 and 6, the solar cell of Example was confirmed to show almost no hysteresis under varied scan rates.

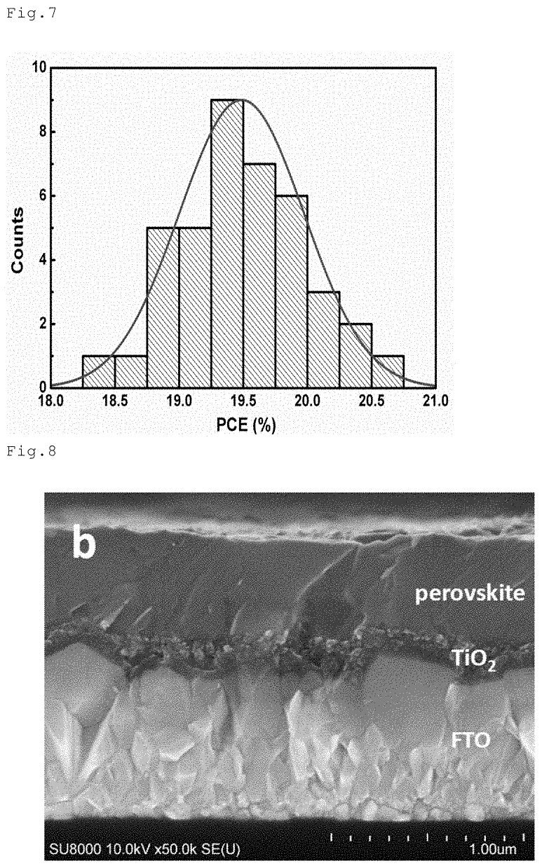

A histogram illustrating distribution of energy conversion efficiency of the solar cells (40 cells) was shown in FIG. 7. From FIG. 7, the perovskite compound (Example 1) formed from the mixture of lead(II) iodide and potassium(I) iodide was confirmed to peak at an energy conversion efficiency of 19.5%, and the energy conversion efficiencies of all 40 solar cells were confirmed to fall within a 1.5% range on both sides of the peak.

FIG. 8 shows an SEM image (at 50000× magnification) of the perovskite compound layer of the solar cell. As seen in FIG. 8, almost no grain boundary was observed in the perovskite compound layer (indicated by “perovskite” in the image).

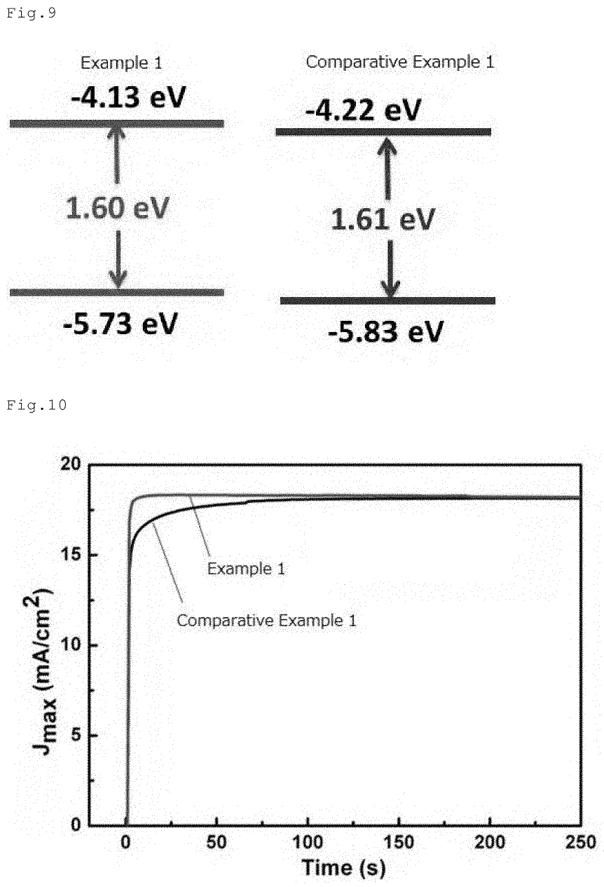

FIG. 9 shows band gap energy diagrams of the perovskite compound layers of the solar cells of Example 1 and Comparative Example 1 (FIG. 9 shows Example 1 on the left, and Comparative Example 1 on the right). The band gap energy of the perovskite compound layer in Example 1 was found to be smaller than that of Comparative Example 1 described later.

FIG. 10 shows changes of transient current (transient response characteristic) at the maximum charge voltage of the solar cells of Example 1 and Comparative Example 1. The maximum charge voltage of the solar cell of Example 1 was found to be 0.95 V, meanwhile the maximum charge voltage of the solar cell of Comparative Example 1 was found to be 0.90 V. As seen in FIG. 10, the solar cell of Example 1 was found to have superior transient response characteristic over that of Comparative Example 1 described later.

### Comparative Example 1

A solar cell was manufactured and evaluated in the same way as in Example 1, except that an N,N-dimethylformamide solution (1.0 ml) free of potassium(I) iodide was used, in place of the perovskite precursor solution prepared by adding 100 μL of a dimethylsulfoxide solution with potassium(I) iodide (249 mg/mL) dissolved therein, to the N,N-dimethylformamide solution (1.0 ml) having lead(II) iodide (0.507 mg), lead(II) bromide (0.073 mg), formamidinium iodide (0.172 mg), and methylammonium bromide (0.022 mg) dissolved therein. The solar cell was found to have an open circuit voltage of 1.11 V, a short circuit current density of 22.6 mA/cm², a shape factor of 0.71, and a conversion efficiency of 17.8%, proven to have characteristics inferior to those of the solar cell of this invention.

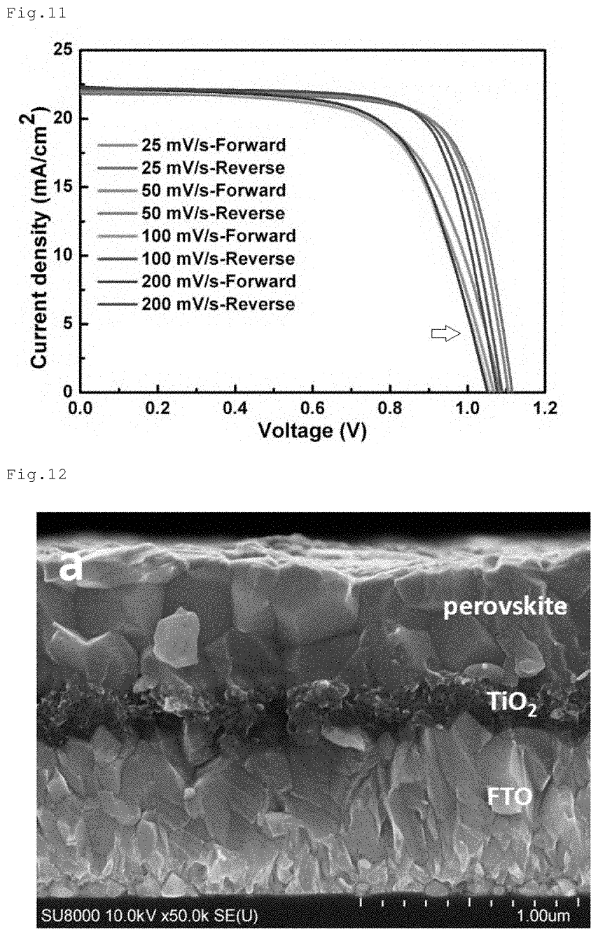

FIG. 11 illustrates I-V curves measured under varied scan rates, and FIG. 6 illustrates hysteresis factors measured under varied scan rates. FIG. 11 shows, at the position indicated by an arrow from the left to right, forward I-V curve measured at a scan rate of 200 mV/s (200 mV/s-Forward), forward I-V curve measured at a scan rate of 100 mV/s (100 mV/s-Forward), forward I-V curve measured at a scan rate of 50 mV/s (50 mV/s-Forward), forward I-V curve measured at a scan rate of 25 mV/s (25 mV/s-Forward), reverse I-V curve measured at a scan rate of 200 mV/s (200 mV/s-Reverse), reverse I-V curve measured at a scan rate of 100 mV/s (100 mV/s-Reverse), reverse I-V curve measured at a scan rate of 50 mV/s (50 mV/s-Reverse), reverse I-V curve measured at a scan rate of 25 mV/s (25 mV/s-Reverse). A hysteresis factor of Comparative Example 1 shown in FIG. 6 was calculated from the I-V curves shown in FIG. 11. From FIGS. 6 and 11, the solar cell of Comparative Example was confirmed to show a hysteresis factor larger than that of Example 1. FIG. 12 shows an SEM image (at 50000× magnification) of the perovskite compound layer of the solar cell. As seen in FIG. 12, a lot of grain boundaries were observed in the perovskite compound layer (indicated by “perovskite” in the image).

Embodiments of this invention, having described above, by no means limit the scope of this invention.

### Test Example 2

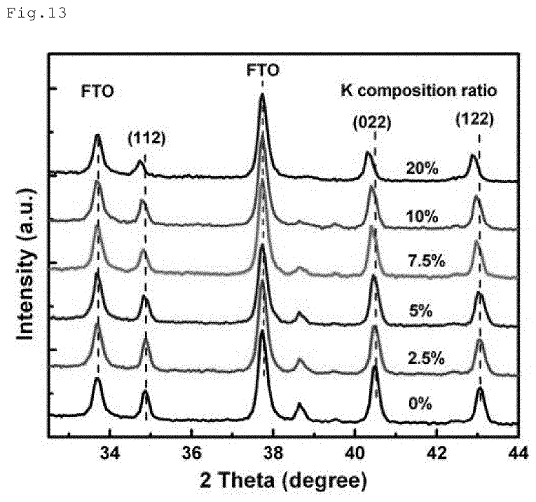

Perovskite precursor solutions were prepared in the same way as in Example 1, except that the amount of addition of potassium(I) iodide was controlled to achieve compositional formulae below. Each precursor solution was then applied dropwise and spin-coated over the substrate, so as to form each perovskite film of 500 nm thick. FIG. 13 shows an XRD chart (2θ) of the obtained films. An XRD chart for 0% in the drawing corresponds to a film formed without adding potassium iodide, with a compositional formula of FA_{0.85}MA_{0.15}Pb(I_{0.85}BR_{0.15})₃. XRD charts for 2.5 to 20% in the drawing correspond to films formed by adding potassium iodide, where an XRD chart for 2.5% corresponds to a film with a compositional formula of K_{0.025}(FA_{0.85}MA_{0.15})_{0.975}Pb(I_{0.85}Br_{0.15})₃, and XRD chart for 5% corresponds to a film with a compositional formula of K_{0.05}(FA_{0.85}MA_{0.15})_{0.95}Pb(I_{0.85}Br_{0.15})₃, an XRD chart for 7.5% corresponds to a film with a compositional formula of K_{0.075}(FA_{0.85}MA_{0.15})_{0.925}Pb(I_{0.85}Br_{0.15})₃, an XRD chart for 10% corresponds to a film with a compositional formula of K_{0.1}(FA_{0.85}MA_{0.15})_{0.9}Pb(I_{0.85}Br_{0.15})₃, and an XRD chart of 20% corresponds to a film with a compositional formula of K_{0.2}(FA_{0.85}MA_{0.15})_{0.8}Pb(I_{0.85}Br_{0.15})₃.

In the formula above, K represents potassium atom, FA represents formamidinium, MA represents methylammonium, Pb represents lead atom, I represents iodine atom, and Br represents bromine atom.

From the XRD chart of FIG. 13, the obtained films were confirmed to have a perovskite crystal structure.

### REFERENCE SIGNS LIST

1 substrate
2 first electrode
3 electron transport layer
4 nanoparticle
5 perovskite layer
6 hole transport layer
7 second electrode
8, 9 lead line

1. An organic-inorganic hybrid material applicable to a perovskite solar cell having a first electrode, an electron transport compound layer arranged on the first electrode, a perovskite compound layer arranged on the electron transport compound layer, a hole transport layer arranged on the perovskite compound layer, and a second electrode arranged on the hole transport layer,
the organic-inorganic hybrid material comprising a compound represented by formula 1 below, with potassium (K) added as a small amount of inorganic monovalent cation: Formula 1
KₓA1_{y}A2_{z}PbX1ₚX2_{q}
wherein K represents potassium, Pb represents lead, A1 and A2 represent freely selectable cations, which may be organic or inorganic, and may be the same; X1 and X2 represent halogen atoms, which may be the same; x represents a numerical value ranging from 0.01 to 0.20; and y, z, p and q represent freely selectable numerical values which satisfy x+y+z=1 and p+q=3.

2. The organic-inorganic hybrid material according to claim 1, wherein the compound represented by formula 1 is formed by a mixture of a lead halide and a non-lead divalent metal cation halide, together with a monovalent cation halide.

3. The organic-inorganic hybrid material according to claim 1, wherein the compound represented by formula 1 is formed by a lead halide and a monovalent cation halide.

4. The organic-inorganic hybrid material according to claim 2, wherein the monovalent cation halide contains a potassium halide.

5. The organic-inorganic hybrid material according to claim 2, wherein the monovalent cation halide contains a potassium halide.

6. The organic-inorganic hybrid material according to claim 2, wherein the monovalent cation halide contains a potassium halide and an alkylammonium halide.

7. The organic-inorganic hybrid material according to claim 3, wherein the monovalent cation halide contains a potassium halide and an alkylammonium halide.

8. The organic-inorganic hybrid material according to claim 1, wherein the compound represented by formula 1 is formed using an alkylammonium halide.

9. The organic-inorganic hybrid material according to claim 6, wherein the alkylammonium halide contains either a methylammonium halide or a formamidinium halide.

10. The organic-inorganic hybrid material according to claim 7, wherein the alkylammonium halide contains either a methylammonium halide or a formamidinium halide.

11. The organic-inorganic hybrid material according to claim 8, wherein the alkylammonium halide contains either a methylammonium halide or a formamidinium halide.

12. The organic-inorganic hybrid material according to claim 1, wherein the electron transfer compound is at least one of zinc oxide, tin oxide, titanium oxide, aluminum oxide, niobium oxide and yttrium oxide.

13. A perovskite solar cell comprising the organic-inorganic hybrid material according to claim 1.
